(19) United States
(12) Patent Application Publication
(10) Pub. No.: US 2025/0331244 A1
(43) Pub. Date: Oct. 23, 2025

(54) VOLTAGE TRIMMING FOR QUBIT CONTROL

(71) Applicant: Quantum Motion Technologies Ltd., London, Greater London (GB)

(72) Inventor: Michael Fogarty, London, Greater London (GB)

(21) Appl. No.: 18/866,590

(22) PCT Filed: Jun. 20, 2023
(86) PCT No.: PCT/EP2023/066678

§ 371 Date: Nov. 18, 2024

(30) Foreign Application Priority Data
Jun. 27, 2022 (EP) 22181352.0

(51) Int. Cl. H10D 48/00; H10D 30/68; H10D 64/27

(52) U.S. Cl. CPC H10D 48/3835; H10D 30/68; H10D 64/27

(57) ABSTRACT

A quantum device comprising an array of quantum dots is disclosed. The quantum device comprises a silicon layer in which quantum dots (201) can be induced by respective gates; gates of the inducible quantum dots (201) for controlling an electrical potential that define the induced quantum dots (201); and integrated circuit elements (204), in particular comprising floating gate field effect transistors, for controlling the voltages of the respective gates, the integrated circuit elements (204) having non-volatile resistance value, RF, which are tunable. The integrated circuit elements (204) have input voltages (Vin) and an output voltages (Vout), wherein the output voltages are dependent on the input voltages and the non-volatile resistance values RF of the different integrated circuit elements. The integrated circuit elements (204) are electrically connected such that their respective output voltages are applied to the gates of the respective inducible quantum dot (201). The gates of the individual quantum dots can thus be addressed using a single input voltage.

### FIELD OF THE INVENTION

The present invention relates to a quantum device suitable for quantum computation.

### BACKGROUND TO THE INVENTION

Qubits are typically arranged in dense arrays as part of a quantum device. In order to perform quantum computations using qubits in an array, each qubit must be addressable.

For small arrays of qubits, each qubit can be addressed using individual control lines. However, this mechanism requires a large number of power sources and as such is difficult to scale up for use with larger qubit arrays.

It is desirable to reduce the number of control lines and equipment required to address qubits within an array. This typically requires a level of uniformity across the array.

There are commonly multiple input elements for addressing qubits within the array, such as electron spin resonance and tunnel coupling. It is desirable for each input element to globally address the qubits in the array; however each input may depend on a qubit property which varies across the array on an individual qubit level. Each of the multiple input elements may therefore need to be adjusted for each qubit in the array accordingly.

For example, in the case of electron spin qubits in silicon, it is desirable to be able to use a single frequency to drive multiple qubits. However, such global control of the electron spins is not straightforward to achieve due to the natural variation in electron g-factor across the device. Although the g-factor can be tuned using an external electric field, the tunable range for each qubit is typically at least an order of magnitude less than the overall g-factor variation across the device.

Accordingly, application of a single frequency may only address 1-10% of the spin qubits in the device.

This problem can be solved using cavity amplitude modulation, which can be used to transform a single frequency input into multiple frequencies covering the range of electron g-factors. In this way, a single frequency can effectively be used to globally control electron spins.

However, the mechanism described above requires the tuning of a voltage reference for each individual qubit, which as described above is inefficient and difficult to scale.

It is desirable to operate an array of qubits on a global scale.

### SUMMARY OF THE INVENTION

An aspect of the invention provides a quantum device, comprising: a silicon layer in which a plurality of quantum dots can be induced; a first gate of a first inducible quantum dot for controlling an electrical potential that defines a first induced quantum dot, wherein the first gate of the first inducible quantum dot is a plunger gate or a barrier gate; a second gate of a second inducible quantum dot for controlling an electrical potential that defines a second induced quantum dot, wherein the second gate of the second inducible quantum dot is a plunger gate or a barrier gate; a first integrated circuit element for controlling the voltage of the first gate; and a second integrated circuit element for controlling the voltage of the second gate. The first integrated circuit element has a first non-volatile resistance value, R_{F}, which is tunable. The second integrated circuit element has a second non-volatile resistance value which is tunable. The first integrated circuit element has an input voltage and a first output voltage, wherein the first output voltage is dependent on the input voltage and the first non-volatile resistance value. The second integrated circuit element has the input voltage and a second output voltage, wherein the second output voltage is dependent on the input voltage and the second non-volatile resistance value. The first and second integrated circuit elements are electrically connected to the first and second gates respectively such that the first and second output voltages are applied to the first gate of the first inducible quantum dot and the second gate of the second inducible quantum dot respectively.

Tuning the resistance value modifies the output voltage applied to the gate of the inducible quantum dot for a fixed input voltage. Advantageously, this means that the output voltage can be adapted according to the physical and electronic properties of each induced quantum dot.

The resistance value is non-volatile. This means that once the resistance value has been tuned, the resistance value remains stable and fixed. The skilled person would understand the term “non-volatile” in this context to mean that a resistance value, i.e. an encoded memory state, of the integrated circuit element can be maintained without a power input. Accordingly a memory state can be encoded and the state can be retained.

The non-volatility of the resistance value has an advantage that the resistance value can be tuned to a set value and then retained for long periods of time. The resistance value can be maintained at a fixed value over the lifetime of the quantum circuit, and at least for the duration of a quantum computation performed using the quantum device. The resistance value may be re-tuned as required, although advantageously re-tuning is not necessary if a fixed resistance value is desired; the resistance value does not need to be refreshed. The integrated circuit element advantageously provides an addressable, non-volatile, analogue memory that is capable of supplying a constant DC voltage offset to the quantum dot in the quantum device.

The gate of the inducible quantum dot is a gate for controlling an electrical potential that defines the induced quantum dot. Preferably, the quantum dot which can be induced in the silicon layer is a gate-defined quantum dot. Typically, a gate-defined quantum dot has multiple gates to confine quantum charge carriers in the quantum dot. Typically, the one or more gates for defining the quantum dot are arranged such that a quantum dot can be induced when suitable bias potentials are applied to the gates. The gate of the inducible quantum dot is optionally a plunger gate. The plunger gate can be used to raise or lower the electrical potential well of the quantum dot to decrease or increase the number of charge carriers confined in the quantum dot respectively.

Advantageously, application of a tailored output voltage to the plunger gate of the inducible quantum dot can be used to configure the induced quantum dot such that one, and only one, electron is confined in the quantum dot during operation of the device. In order to achieve this, the non-volatile resistance value of the integrated circuit element is preferably tuned such that the output voltage applied to the plunger gate is above the voltage required to trap or confine one electron, V₁ₑ, and below the voltage required to trap or confine two electrons, V₂ₑ. V₁ₑ and V₂ₑ may vary from one quantum dot to the next, and the variation may be substantial.

Optionally, the gate of the inducible quantum dot is a barrier gate. The barrier gate can be used to raise or lower an electrostatic barrier which defines an edge of the electrical potential well of the quantum dot to reduce or increase the coupling strength between the quantum dot and a neighbouring confinement region. The neighbouring confinement region may be a zero-dimensional confinement region, i.e. another quantum dot, a one-dimensional confinement region, for example an elongated quantum dot, or a two-dimensional confinement region, i.e. a charge carrier reservoir.

Advantageously, application of a customized output voltage to the barrier gate of the inducible quantum dot can be used to adapt the coupling strength according to performance requirements. For example, a two-qubit interaction may be enabled by modifying the output voltage applied to the barrier gate to reduce the height of the electrostatic barrier between two neighbouring quantum dots. The required output voltage applied to the barrier gate will vary across the quantum device and therefore it is beneficial to be able to modify the voltage applied to the barrier gate as required.

Optionally, one inducible quantum dot may have more than one barrier gate to define multiple edges of the electrical potential well of the quantum dot. For example, the inducible quantum dot may be defined with one plunger gate and two barrier gates. Each of the barrier gates and the plunger gates may have a corresponding integrated circuit element for controlling the voltage of the gate. Preferably, the non-volatile resistance value of each integrated circuit element can be independently tuned. Advantageously the tuning of each integrated circuit element provides a mechanism whereby variations in quantum dot properties across the device can be catered for on an individual quantum dot level.

The properties of the induced quantum dot may vary significantly across the quantum device depending on the location within the quantum device and any differences introduced during fabrication. For example, the electron g-factor may vary due to surface roughness of the interface between the silicon layer and a silicon oxide layer (Si/SiOₓ), even on the scale of single atomic step. A monoatomic shift (i.e. a step of a single atom) in the interface results in a sign inversion of the Dresselhaus coefficient (β) but the Rashba coefficient (α) remains unchanged. Electron g-factor and Stark shift in opposite valleys of the same dot also vary significantly. Similarly, the first electron energy may vary across the device due to changes in underlying physical properties of the device. Additionally, the second electron energy may vary across the device for similar reasons. Furthermore, tunnel coupling properties between adjacent confinement regions, such as quantum dots or charge reservoirs, in the device can vary due to changes in the surface roughness or other physical properties of the device. Output voltages applied to tunnel barriers may need to be adjusted to account for variations in tunnel coupling strength.

The quantum device is a silicon-based quantum device having a silicon layer. The silicon layer may be intrinsic silicon, isotopically pure silicon Si²⁸, or doped silicon for example. The quantum device typically comprises additional layers for supporting the silicon layer and for providing control circuitry.

The integrated circuit element has a non-volatile resistance value which is tunable. This may be achieved by tuning the threshold voltage of the integrated circuit element. A gate voltage may be applied to the integrated circuit element. If the gate voltage is greater than the threshold voltage for an n-type integrated circuit element, the integrated circuit element is “on”. If the gate voltage is lower than the threshold voltage for an n-type integrated circuit element, the integrated circuit element is “off”. Below the threshold voltage, i.e. in the sub-threshold range, the channel resistance of the circuit element is high and typically increases exponentially with reduced gate voltage. The channel resistance of the circuit element is a non-volatile resistance value.

The integrated circuit element may be n-type, p-type or ambipolar. If the gate voltage is lower, i.e. more negative, than the threshold voltage for a p-type integrated circuit element, the integrated circuit element is “on”. If the gate voltage is higher than the threshold voltage for a p-type integrated circuit element, the integrated circuit element is “off”. An ambipolar integrated circuit element has two threshold voltages. Below a first threshold voltage, the integrated circuit element is “on” and the transport is p-type, i.e. the charge carriers are holes. Between the first threshold voltage and a second threshold voltage, the integrated circuit is “off”. Above the second threshold voltage, the integrated circuit element is “off” and the transport is n-type, i.e. the charge carriers are electrons.

The integrated circuit element is electrically connected to the gate such that the output voltage is applied to the gate of the inducible quantum dot. When the quantum dot is induced in the silicon layer, the integrated circuit element is electrically connected to the induced quantum dot.

The output voltage controls the voltage of the gate which controls an electrical potential that defines the quantum dot. In an example in which the gate is a plunger gate, the output voltage is typically adjusted such that the quantum dot either contains one electron (i.e. the dot is filled), or zero electrons (i.e. the dot is empty). This is typically achieved by modifying the input voltage.

The quantum device is preferably manufactured using complementary metal-oxide-semiconductor (CMOS) fabrication techniques. This advantageously facilitates the production of the device.

Optionally, the integrated circuit element comprises a field-effect transistor (FET). A FET typically comprises three terminals: a gate, a source and a drain. Optionally, the input and output voltages correspond to the source and drain terminals. Current flows between the source and the drain and is characterised by the channel resistance. The channel resistance is determined by the applied gate voltage (i.e. the gate voltage applied to the integrated circuit element) and the threshold voltage, and the channel resistance is non-volatile and tunable. Different types of FETs may be suitable for use as the integrated circuit element. Preferably, the integrated circuit element is non-volatile and has long-term charge stability.

Preferably, the integrated circuit element comprises an electrically isolated element which is capacitively coupled via close promixity to the source-drain channel and the gate. The electrically isolated element can advantageously be charged and discharged to encode different non-volatile memory states. The encoded memory states advantageously do not require refreshing to be maintained.

For example, the first and/or second integrated circuit element may comprise a floating gate metal-oxide-semiconductor field-effect transistor (FGMOS). The integrated circuit element may be a FGMOS. An FGMOS typically comprises a control gate and a floating gate (also referred to as a floating island). The floating gate typically provides the electrically isolated element of the integrated circuit element. Advantageously, FGMOS devices have been shown to exhibit hysteretic behaviour which results in a tunable and non-volatile resistance value.

Typically, the electrically isolated element can be charged or discharged to tune the resistance value. The charging and discharging of the electrically isolated, or “floating”, element preferably modifies the threshold voltage such that for a fixed gate voltage applied to the integrated circuit element, the resistance value is modified. The programmed charge state of the electrically isolated element is typically non-volatile and stable. This characteristic enables the tunable resistance value to be tuned to a set resistance value and maintained at the set resistance value over time, thus ensuring the stable, reliable operation of the quantum device.

Alternatively, the first and/or second integrated circuit element may comprise a gate-defined multiple quantum dot device. Advantageously, these devices have also been found to exhibit hysteretic behaviour. The resistance value of the multiple quantum dot device can be tuned to a set resistance value and maintained at the set resistance value in the long-term. The hysteretic behaviour relates to the ability to shift the threshold voltage to more positive or more negative values to tune the value of the channel resistance of the integrated circuit element.

Optionally, the gate-defined multiple quantum dot device may comprise a silicon nanowire. Typically, the gate-defined multiple quantum dot device comprises a plurality of gates.

The quantum device is preferably arranged such that the induced quantum dot has a fixed resistance (for a fixed temperature) and the integrated circuit element has a modifiable resistance. The induced quantum dot and integrated circuit element are preferably arranged such that the voltage applied to the induced quantum dot is less than the voltage applied to the integrated circuit element. The level of reduction may be controllable by tuning the modifiable resistance value of the integrated circuit element to control the output voltage.

Preferably, the first induced quantum dot has a first resistance value, R_{D}. The resistance value of the induced quantum dot, R_{D}, is typically dependent on the temperature of the quantum device: as the temperature decreases the first resistance value, R_{D}, may increase. Quantum computations are typically performed at cryogenic temperatures and therefore the first resistance value is typically large. For example, at 4 kelvin, the first resistance value may be approximately 1×10⁶ to 1×10⁹ ohms. Advantageously, the resistance value is non-volatile even at low temperatures and therefore a set resistance value can be maintained at the device operating temperature.

The non-volatile resistance value, i.e. the channel resistance of the integrated circuit element, R_{F}, is typically dependent on the threshold voltage. For a fixed input voltage and an n-type integrated circuit element, the non-volatile resistance value, R_{F}, is larger for a larger threshold voltage. The integrated circuit element is preferably operated in the deep sub-threshold range. This means that during the operation of the quantum device, the gate voltage is preferably below the threshold voltage. In the sub-threshold range, the channel resistance of the integrated circuit element typically increases exponentially with reduced gate voltage.

The integrated circuit element and the induced quantum dot are preferably arranged such that the input voltage is distributed between the components. The arrangement may be referred to as a resistive divider, voltage divider or potential divider. In this arrangement, the first output voltage, Vₒᵤₜ, is preferably proportional to the input voltage, Vᵢₙ, with a constant of proportionality equal to R_{D}/(R_{F}+R_{D}).

Advantageously, when the integrated circuit element is operated in the deep sub-threshold range, the non-volatile resistance, R_{F}, is large, and can be tuned to be comparable to the large fixed resistance, R_{D}, of the quantum dot. This means the range of possible output voltages, Vₒᵤₜ, can be selected such that the quantum dot can be emptied or filled. Typically, “empty” means there are no electrons in the quantum dot and “filled” means there is one electron in the quantum dot. Typically, it is possible for more than one electron to be confined in the quantum dot but this is typically avoided if the quantum dots are to be used as qubits in the quantum device.

The quantum device optionally further comprises a tuning field effect transistor, FET, wherein the tuning FET is electrically connected to the first or second integrated circuit element. The tuning FET may be configured to enable or disable a tuning voltage for the first or second integrated circuit element respectively.

The tuning FET can advantageously be used to enable or disable a tuning voltage by charging and discharging the integrated circuit element. Specifically, the tuning FET may be used to charge and discharge a floating element of the integrated circuit element. Typically, the output of the tuning FET is connected to the gate of the integrated circuit element. For example, the tuning FET may comprise source, drain and gate terminals and the drain terminal of the tuning FET may be connected to the control gate of a FGMOS. The tuning FET preferably acts as a switch. When the tuning FET is “off”, voltages applied to the source terminal of the tuning FET are not transmitted and the tuning voltage or tuning signal is disabled. When the tuning FET is “on”, current can flow between the source and drain terminals of the tuning FET such that a voltage applied to the source terminal can be transmitted to the drain terminal which may be connected to the integrated circuit element. Therefore when the tuning FET is “on”, a tuning voltage or tuning signal is enabled.

The tuning FET may be used to tune the non-volatile resistance value of the integrated circuit element to control the occupation of the quantum dot by modifying the voltage applied to the quantum dot gate. The first and second quantum dots of the quantum device can be induced in a silicon layer and the first and/or second induced quantum dots are preferably suitable for use as qubits. The quantum dot is preferably a gate-defined quantum dot and the voltage of the gate of the induced quantum dot can be modified to add an electron or remove an electron from the dot. If the quantum dot is populated, the quantum dot may be suitable for use as a qubit. For example, the qubit may be an electron spin qubit. In this example, the two measurable states of the qubit are spin up and spin down. The induced quantum dot may therefore advantageously provide a carrier for quantum information in the quantum device.

In order to address and manipulate the qubit to perform quantum operations, the quantum device optionally comprises qubit pulsing control circuitry configured to modify the state of the first and/or second qubit. The qubit pulsing control circuitry is preferably electrically connected between the first and/or second integrated circuit element and the first and/or second induced quantum dot respectively. Preferably, the qubit pulsing control circuitry is electrically connected between the integrated circuit element and the gate of the inducible quantum dot. The incorporation of qubit pulsing control circuitry advantageously presents a mechanism for controlling the state of the qubit as part of a quantum computation. The qubit pulsing control circuitry may coupled using a bias-tee configuration, for example the qubit pulsing control circuitry may be electrically connected using a capacitor to provide AC coupling. The qubit pulsing control circuitry may include an arbitrary waveform generator (AWG) for example. The AWG may be used to provide signals to the quantum device to control the state of one or more qubits.

Furthermore, in order to read out the state of the qubit, the quantum device optionally comprises qubit readout control circuitry configured to read out the state of the first and/or second qubit. The qubit readout control circuitry is preferably connected between the first and/or second integrated circuit element and the first and/or second induced quantum dot respectively. Preferably, the qubit readout control circuitry is electrically connected between the integrated circuit element and the gate of the inducible quantum dot. The incorporation of qubit readout control circuitry advantageously allows the state of the qubit to be read out or inferred as part of a quantum computation. For example, the state of the qubit may be read out after performing one or more quantum operations on the qubit. The qubit readout control circuitry may comprise an inductor and a capacitor, for example. The qubit readout control circuitry may comprise an LC resonator circuit, otherwise known as a tank circuit, an LC resonator or a resonator circuit.

A plurality of qubits are involved in a quantum computation. The quantum device therefore includes a plurality of quantum dots for use as qubits.

The first output voltage is applied to the first gate of the first inducible quantum dot. The second output voltage is applied to the second gate of the second inducible quantum dot. Alternatively, the first and second gates can both be used for controlling an electrical potential that defines the same induced quantum dot. For example, the first gate may be a plunger gate of the first inducible quantum dot and the second gate may be a barrier gate of the first inducible quantum dot. In this alternative example, the first output voltage is applied to the plunger gate of the first inducible quantum dot and the second output voltage is applied to a barrier gate of the first inducible quantum dot.

This advantageously allows global control of the quantum dots. The same input voltage can be used to apply two output voltages; the first and second output voltages may be different. The first and second non-volatile resistance values can be tuned to control the respective voltages of the first and second gates of the first and second induced quantum dots respectively according to their properties. Beneficially, this provides the capability to adapt the first and second output voltages according to the properties of the first and second inducible quantum dots respectively. If the first and second inducible quantum dots have similar properties, the first and second output voltages may be similar.

More generally, any number of quantum dots may be induced in the silicon layer subject to practical fabrication constraints. For example, the device may be configured such that approximately 10⁹ quantum dots can be induced in the silicon layer. For each gate of an inducible quantum dot, the quantum device preferably comprises a corresponding integrated circuit element for applying a voltage to the gate of the induced quantum dot. There are typically a plurality of inducible quantum dots and a plurality of gates used to define each quantum dot. Each integrated circuit element typically has a non-volatile resistance value which is tunable. Each integrated circuit element preferably has the same input voltage. The output voltage of each integrated circuit element is typically dependent on the input voltage and the non-volatile resistance value of that integrated circuit element. Each integrated circuit element is preferably arranged such that the output voltage is applied to the corresponding gate of the inducible quantum dot. Advantageously, when the quantum device comprises an integrated circuit element for each gate of an inducible quantum dot, the voltage of each gate can be individually tailored using a single input voltage.

In another example, the quantum device may have a unit cell construction in which each unit cell typically comprises two or more quantum dots and the unit cell is repeated in a one-dimensional or two-dimensional array. The quantum device optionally has two or more input voltages corresponding to each quantum dot in the unit cell. This configuration advantageously provides a mechanism for performing complex operations between a plurality of qubits whilst reducing the control circuitry required.

In another example, each quantum dot in the array may be defined by a plunger gate and two barrier gates. A first input voltage may be used to address the plunger gate of each quantum dot in the array. Second and third input voltages may be used to address first and second barrier gates respectively of each quantum dot in the array. Each gate preferably has a corresponding integrated circuit element to adjust the output voltage applied to the gate.

If the quantum device includes more than one gate and/or more than one inducible quantum dot, the quantum device may further comprise a crossbar array configured to be selectively electrically connected to the first and/or second integrated circuit elements. The selective electrical connection advantageously allows for the individual tuning of the first and/or second integrated circuit elements to account for their different properties.

Another aspect of the invention provides a method for using a quantum device comprising: a silicon layer in which a plurality of quantum dots can be induced; a first gate of a first inducible quantum dot for controlling an electrical potential that defines a first induced quantum dot, wherein the first gate of the first inducible quantum dot is a plunger gate or a barrier gate; a second gate of a second inducible quantum dot for controlling an electrical potential that defines a second induced quantum dot, wherein the second gate of the second inducible quantum dot is a plunger gate or a barrier gate; a first integrated circuit element for controlling the voltage of the first gate, the first integrated circuit element having a first non-volatile resistance value, R_{F}, which is tunable; a second integrated circuit element for controlling the voltage of the second gate, the second integrated circuit element having a second non-volatile resistance value which is tunable; and a crossbar array for selecting one or more integrated circuit elements. The method comprises: inducing the first and second quantum dots; selecting the first integrated circuit element; tuning the first non-volatile resistance value of the first integrated circuit element to a first set non-volatile resistance value; selecting the second integrated circuit element; tuning the second non-volatile resistance value of the second integrated circuit element to a second set non-volatile resistance value; applying an input voltage to the first and second integrated circuit elements, wherein a first output voltage of the first integrated circuit element and a second output voltage of the second integrated circuit element are dependent on the input voltage and the first and second set non-volatile resistance values respectively; applying the first output voltage of the first integrated circuit element to the first gate of the first induced quantum dot; and applying the second output voltage of the second integrated circuit element to the second gate of the second induced quantum dot.

Tuning the resistance values of the integrated circuit elements modifies the respective output voltages. An advantage of this method is that the set non-volatile resistance values can be controlled to control the voltages applied to the gates of the inducible quantum dots according to the specific properties of the quantum dots.

The set-point for the non-volatile resistance value may be selected such that a qubit resonance line is targeted. It is desirable to globally apply a driving frequency to the qubits, but the qubit resonance varies according to the electron g-factor which typically varies greatly across the device. Advantageously, this method can be used to provide tailored voltages for each quantum dot in the quantum device to control the occupancy of the quantum dot.

The set-point for the non-volatile resistance value may be selected based on alternative requirements such as a target tunnel coupling strength. For example, for a particular electrical potential well, the barrier height required to provide a specific tunnel coupling strength may differ depending on the properties of the device in the region of the formation of the electrical potential well. Therefore, different output voltages are required across the quantum device.

Generally, the non-volatile resistance value may be selected to produce different output voltages from the same input voltage for any chosen output requirements. The output voltages are typically required to be different due to variation in electronic and/or physical properties across the quantum device. Generally, the quantum device may have a plurality of input voltages which correspond to different functions.

Optionally, if the quantum device further comprises a tuning field effect transistor (FET) comprising source, drain and gate terminals, the step of tuning the first or second non-volatile resistance value of the first or second integrated circuit element to the first or second set non-volatile resistance value respectively may comprise: enabling the tuning FET by applying a voltage to the gate terminal of the tuning FET to allow current to pass between the source and drain terminals of the tuning FET; and applying a tuning voltage to the tuning FET. The tuning FET is preferably configured to enable or disable a tuning voltage for the integrated circuit element. The tuning FET is preferably electrically connected to the first or second integrated circuit element such that applying the tuning voltage to the enabled tuning FET modifies the non-volatile resistance value of the first or second integrated circuit element respectively. Preferably, application of a tuning voltage to the enabled tuning FET modifies the channel resistance of the integrated circuit element, and application of the tuning voltage to the disabled tuning FET does not modify the channel resistance of the integrated circuit element. The first and second set non-volatile resistance values are typically dependent on the tuning voltage.

The tuning FET comprises source, drain and gate terminals. The tuning FET may be n-type, p-type or ambipolar. Enabling an n-type tuning FET typically comprises applying a voltage to the gate terminal which is larger than the threshold voltage of the tuning FET. This turns the tuning FET “on”. In this state, the channel resistance of the tuning FET is low and there is a conductive path between the source and drain terminals. Once the tuning FET is enabled, a tuning voltage applied to the source terminal of the tuning FET can be passed to the integrated circuit element. Preferably, the drain terminal of the tuning FET is electrically connected to a gate terminal of the integrated circuit element. This may, for example, be a control gate or a top gate.

The enabled tuning FET can advantageously be used to tune the resistance value by charging and discharging the integrated circuit element. The enabled tuning FET may be used to charge and discharge an electrically isolated element of the integrated circuit element. For example, if the integrated circuit element is a FGMOS device, charge may be built up on the floating gate and the level of charge will affect the threshold voltage, which will impact the channel resistance of the device. The channel resistance is typically a non-volatile resistance value. The floating gate which holds the built-up charge is capacitively coupled to the site of the quantum dot. This adds a voltage potential, V_{FG}, directly to the quantum dot based on the charge held by the floating gate, Q, and the capacitive coupling C, where V_{FG}=Q/C.

Optionally, the quantum device may be configured such that there are a plurality of inducible quantum dots in the silicon layer. For example, the gate may be a first gate of a first inducible quantum dot for controlling an electrical potential that defines the first induced quantum dot; and the integrated circuit element may be a first integrated circuit element for controlling the voltage of the first gate, the first integrated circuit element having a first non-volatile resistance value which is tunable. Optionally, a second quantum dot can be induced in the silicon layer and the quantum device further comprises: a second gate of the second inducible quantum dot for controlling an electrical potential that defines the second induced quantum dot; a second integrated circuit element for controlling the voltage of the second gate. The second integrated circuit element preferably has a second non-volatile resistance value which is tunable. The quantum device may also comprise a crossbar array for selecting one or more integrated circuit elements.

For a quantum device comprising first and second inducible quantum dots, the method typically comprises: selecting the first integrated circuit element; tuning the first non-volatile resistance value of the first integrated circuit element to a first set non-volatile resistance value; selecting the second integrated circuit element; tuning the second non-volatile resistance value of the second integrated circuit element to a second set non-volatile resistance value; applying the input voltage to the first and second integrated circuit elements, wherein a first output voltage of the first integrated circuit element and a second output voltage of the second integrated circuit element are dependent on the input voltage and the first and second set non-volatile resistance values respectively; applying the first output voltage of the first integrated circuit element to the first gate of the first inducible quantum dot; and applying the second output voltage of the second integrated circuit element to the second gate of the second inducible quantum dot.

This method advantageously allows global control of the induced quantum dots. The same input voltage can be used to apply two output voltages which may be different. Advantageously, different g-factors, electron energies and tunnelling coupling strengths, can be addressed with different output voltages using the same input voltage. Typically different functions are addressed using different input voltages, for example one input voltage may be used to apply multiple output voltages to address different tunnelling coupling strengths, and another input voltage may be used to apply multiple output voltages to address different first electron energies. The first and second non-volatile resistance values can be tuned to first and second set non-volatile resistance values to control the voltages of the first and second gates of the respective induced quantum dots. The gates of the quantum dots can thus be addressed individually using a single input voltage.

Generally, the quantum device may comprise n inducible quantum dots, m gates for each quantum dot, and m×n integrated circuit elements, each gate of a quantum dot electrically connected to a respective integrated circuit element. In an alternative example, the number of gates for each inducible quantum dot may vary across the quantum device. For example, a barrier gate may provide a barrier for two adjacent quantum dots. Generally, the method may comprise selecting each integrated circuit element in turn and tuning its non-volatile resistance value to its set value. Subsequently, the method may generally comprise applying the input voltage to the m×n integrated circuit elements; the output voltages applied to the gates of the quantum dots depend on the input voltage and the set non-volatile resistance values. This method advantageously provides global control of an array of quantum dots. One input voltage can be used to apply multiple output voltages to quantum dots with different properties. This advantageously reduces the complexity of the method and reduces the required control circuitry.

Optionally, there may be m input voltages. Generally, each input voltage may applied to n integrated circuit elements, wherein each of the n integrated circuit elements correspond to an inducible quantum dot and each of the m input voltages correspond to gates having different functions.

An aspect of the invention provides a quantum device, comprising: a silicon layer in which a quantum dot can be induced; a gate of the inducible quantum dot for controlling an electrical potential that defines the induced quantum dot; and an integrated circuit element for controlling the voltage of the gate. The integrated circuit element has a non-volatile resistance value, R_{F}, which is tunable. The integrated circuit element has an input voltage and an output voltage, wherein the output voltage is dependent on the input voltage and the non-volatile resistance value. The integrated circuit element is electrically connected to the silicon layer such that the output voltage is applied to the gate of the inducible quantum dot.

Another aspect of the invention provides a method for using a quantum device comprising: a silicon layer in which a quantum dot can be induced; a gate of the inducible quantum dot for controlling an electrical potential that defines the induced quantum dot; and an integrated circuit element for controlling the voltage of the gate, the integrated circuit element having a non-volatile resistance value which is tunable. The method comprises: tuning the non-volatile resistance value of the integrated circuit element to a set non-volatile resistance value; applying an input voltage to the integrated circuit element, wherein an output voltage of the integrated circuit element is dependent on the input voltage and the set non-volatile resistance value; and applying the output voltage of the integrated circuit element to the gate of the inducible quantum dot.

### BRIEF DESCRIPTION OF THE DRAWINGS

Embodiments of the invention will now be described with reference to the accompanying drawings in which:

FIG. 1 is a circuit diagram of a prior art quantum device;

FIG. 2 is a circuit diagram of a quantum device;

FIG. 3 is a circuit diagram of a quantum device;

FIG. 4 is a circuit diagram of a quantum device;

FIG. 5 is a circuit diagram of a quantum device; and

FIG. 6 is a cross-sectional side view of an integrated circuit element.

### DETAILED DESCRIPTION

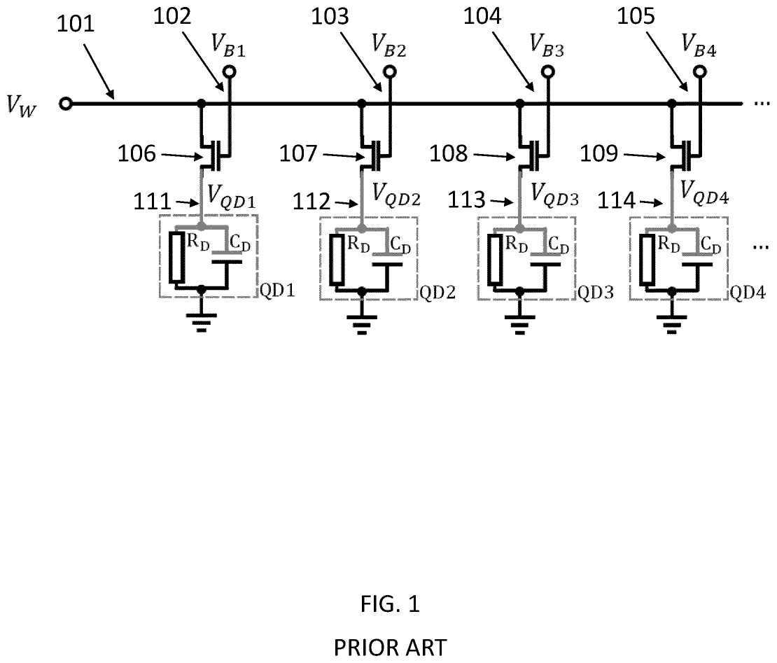

FIG. 1 is a circuit diagram of a prior art quantum device. The device is described in Veldhorst et al, “Silicon CMOS architecture for a spin-based quantum computer”, DOI: 10.1038/s41467-017-01905-6 (2017). FIG. 1 illustrates four quantum dots QD1, QD2, QD3, QD4. Each quantum dot QD1, QD2, QD3, QD4 is a single quantum dot and is schematically illustrated as a resistor R_{D} and a capacitor C_{D}. The resistance and capacitance of each quantum dot typically varies. The quantum dots QD1-QD4 can be addressed using word and bit lines 101-105 which are connected to the quantum dots QD1-QD4 through transistors 106-109. Each transistor 106-109 has a source terminal, drain terminal and gate terminal.

FIG. 1 illustrates a word line 101 electrically connected to the source terminal of four transistors 106, 107, 108, 109. Each bit line 102, 103, 104, 105 is electrically connected to the gate terminal of a transistor 106, 107, 108, 109. Each quantum dot QD1, QD2, QD3, QD4 is electrically connected to the drain terminal of a transistor 106, 107, 108, 109. For example, the gate terminal of the first transistor 106 is electrically connected to the first bit line 102; the source terminal of the first transistor 106 is electrically connected to the word line 101; and the drain terminal of the first transistor 106 is electrically connected to the first quantum dot QD1.

The bit lines 102-105 can be used to address each of the respective quantum dots QD1-QD4. This can be achieved by applying a bias potential V_{B1}, V_{B2}, V_{B3}, V_{B4}, to the relevant bit line. When a suitable bias potential is applied to a bit line, the electrically connected transistor is turned on. When the transistor is on, the channel resistance, i.e. the resistance between the source and drain terminals of the transistor, is low. When the transistor is off, the channel resistance is high.

For example, to address the second quantum dot QD2, a bias potential V_{B2} can be applied to the second bit line 103. Applying a large enough bias potential V_{B2} to the second bit line 103 turns the second transistor 107 on. When the second transistor 107 is on, current can flow between the word line 101 and the second quantum dot QD2 because the channel resistance is low. The current flow will depend on the bias potential V_{W} applied to the word line 101: a larger applied bias potential V_{W} will increase the current flow.

The quantum device illustrated in FIG. 1 includes charge storage electrodes 111, 112, 113, 114, or floating memory gate electrodes. When a transistor 106-109 is on, the bias potential V_{W} applied to the word line 101 can be controlled to charge or discharge the electrically connected charge storage electrode 111-114. Charging or discharging a charge storage electrode 111-114 can be used to tune the electrical properties of the electrically connected quantum dot QD1-QD4.

The charge storage electrodes 111-114 are tuned such that the voltage applied to the quantum dots QD1-QD4 is within an acceptable range for qubit control. However, the voltage on the charge storage electrode 111-114 decays subject to a voltage decay time-constant τ=RC, wherein R is the total resistance including the resistance of the quantum dot, R_{D}, and wherein C is the total capacitance including the capacitance of the quantum dot, C_{D}, and other parasitic capacitances within the quantum device. The total capacitance C typically includes the input capacitance on the source-side of the transistor 106-109. Due to the decay of the voltage on the charge storage electrode 111-114, the applied voltage must therefore be periodically refreshed to keep the voltage within the acceptable range. The decay may be due to leakage or variations in the capacitive coupling to nearby structures. This system is similar to a dynamic random access memory, DRAM, system.

In order to refresh the charge level on the charge storage electrode 111-114 to re-tune the memory following decay, the transistors 106-109 must be re-enabled using the bit and word lines 101-105. The quantum device illustrated in FIG. 1 can be used to individually tune qubits within a qubit array. However, this solution has a number of disadvantages. For example, the periodic refreshing of the volatile memory element (the charge storage electrodes 111-114) requires extensive control circuitry to be enabled regularly during device operation. This results in a relatively high power consumption. Furthermore the initial writing of individual tuning points to the charge storage electrodes 111-114 is difficult to achieve and difficult to maintain without corruption when applying the desired control signals.

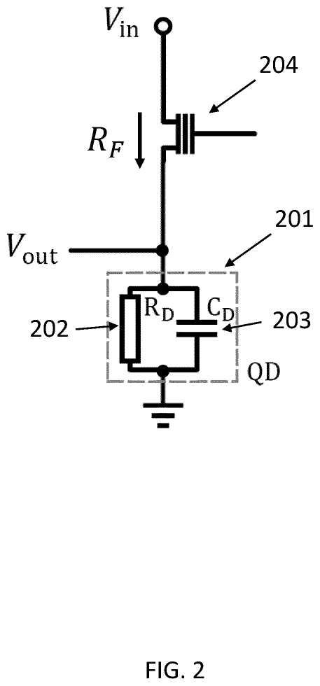

FIG. 2 is a circuit diagram illustrating a portion of a quantum device in accordance with an embodiment of the invention. The circuit includes a quantum dot 201 which is a single quantum dot. The quantum dot 201 can be induced in a silicon layer (not shown) by applying a bias potential Vₒᵤₜ to the quantum dot 201. The induced quantum dot 201 is suitable for use as a qubit in the quantum device when the quantum dot 201 is occupied by a single electron. A voltage is applied to the plunger gate of the quantum dot to raise or lower the electrical potential well of the quantum dot to decrease or increase the number of confined electrons. The plunger gate voltage required to occupy the quantum dot 201 with a single electron is dependent on the properties of the quantum dot 201.

The quantum dot 201 is schematically illustrated as a resistor 202 and capacitor 203 arranged in parallel. The quantum dot 201 is electrically grounded. The resistor 202 has a resistance R_{D}; the capacitor 203 has a capacitance C_{D}. The resistance R_{D} and capacitance C_{D} depend on the properties of the quantum dot 201. Accordingly, for a typical device comprising an array of quantum dots for use as qubits, the resistance and capacitance of each quantum dot varies across the array.

The circuit illustrated in FIG. 2 also includes an integrated circuit element 204. The integrated circuit element 204 has a source terminal, a drain terminal and a gate terminal. In this example, the integrated circuit element 204 has two gate terminals: a control gate terminal and a floating gate terminal. The control gate is electrically connected to a voltage source (not shown). The floating gate is an electrically isolated element which is capacitively coupled via close proximity to the control gate and to the source and drain terminals.

The integrated circuit element 204 has a tunable non-volatile resistance value, R_{F}, which can be used to encode memory states in a quasi-analogue manner. The non-volatile resistance value can be tuned and maintained over long time periods during operation of the quantum device. The quantum device is typically operated at cryogenic temperatures. The integrated circuit element 204 provides a FLASH-memory-like element which is long-term stable at device operating temperatures. This removes the need to refresh the memory state as once the memory state has been encoded there is negligible decay. The set memory state does not drift appreciably over time.

The non-volatile resistance value, R_{F}, is the channel resistance of the integrated circuit element 204. The channel resistance R_{F} is dependent on the physical properties of the integrated circuit element 204 such as its dimensions and the threshold voltage. An input voltage Vᵢₙ can be applied to the source terminal of the integrated circuit element 204. The output voltage Vₒᵤₜ of the integrated circuit element 204 depends on the tunable channel resistance R_{F}, i.e. the resistance between the source and drain terminals, and the resistance of the quantum dot 201, R_{D}.

In this example, the integrated circuit element 204 is an n-type field-effect transistor. The integrated circuit element 204 has a threshold voltage Vₜₕ. When a bias potential below the threshold voltage is applied to the control gate, the integrated circuit element 204 is “off” and the channel resistance R_{F} is very large. In the sub-threshold range, the channel resistance R_{F} continues to increase exponentially with decreasing gate voltage. When a bias potential above the threshold voltage is applied to the control gate, the integrated circuit element 204 is “on” and the channel resistance R_{F} is very small. During normal operation of the quantum device, i.e. when quantum operations are being performed, the integrated circuit element is in the sub-threshold range.

The non-volatile resistance value R_{F} of the integrated circuit element 204 can be tuned by adjusting the charge on the electrically isolated element. The electrically isolated element can be charged and discharged by adjusting the bias potential applied to the control gate. For a particular control gate voltage applied to the integrated circuit element 204, a larger channel resistance R_{F} corresponds to a more positive threshold voltage Vᵢₙ for an n-type integrated circuit element. Accordingly, the channel resistance R_{F} can be modified by shifting the threshold voltage which is achieved by altering the charge level on the electrically isolated element.

The circuit illustrated in FIG. 2 accordingly provides a resistive divider. The input voltage, Vᵢₙ, is reduced according to the relative values of resistance R_{D} of the quantum dot 201 and the channel resistance R_{F} of the integrated circuit element 204. The output voltage Vₒᵤₜ of the integrated circuit element 204 depends on the input voltage, Vᵢₙ, and the non-volatile resistance value, R_{F}. The output voltage Vₒᵤₜ is applied to a gate of the induced quantum dot 201 and can be calculated according to the following equation.

$${V}_{out} = \frac{{R}_{D}}{{R}_{F} + {R}_{D}} {V}_{in}$$

The resistive element R_{D} of the quantum dot 201 is typically due to the cumulative leakage to electrical ground present in complementary metal-oxide-semiconductor (CMOS) fabrication techniques. The resistance R_{D} is dependent on temperature and at cryogenic temperatures, R_{D} is typically very large. The channel resistance R_{F} is preferably large in order to provide a range of output voltages Vₒᵤₜ from a single input voltage Vᵢₙ. Accordingly, the integrated circuit element 204 is typically operated in the deep sub-threshold regime.

In the example illustrated in FIG. 2, the gate of the quantum dot 201 is electrically connected to the drain terminal of the integrated circuit element 204. In an alternative example the gate of the quantum dot may be electrically connected to the electrically isolated element and the drain terminal may be electrically grounded.

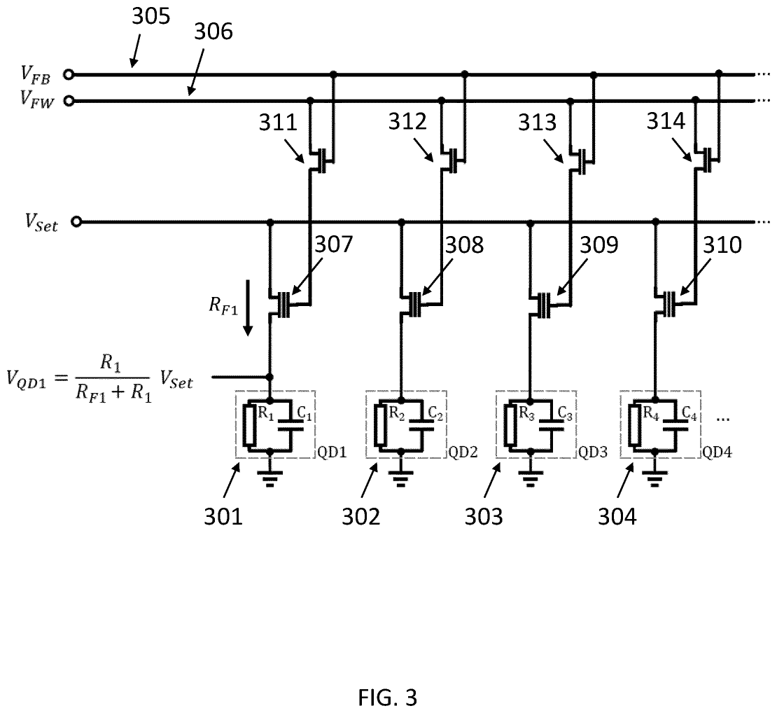

FIG. 3 is a circuit diagram illustrating a portion of a quantum device in accordance with an embodiment of the invention. The circuit includes four quantum dots 301, 302, 303, 304 which are each illustrated schematically as a resistor having resistance Rn and a capacitor having a capacitance Cₙ arranged in parallel, where n=1, 2, 3, 4. The resistance Rₙ and capacitance Cₙ of each quantum dot 301-304 varies between quantum dots due to manufacturing tolerances and underlying material properties. Each of the quantum dots 301-304 are electrically grounded and can be induced in a silicon layer of the quantum device by applying a suitable voltage to gates which are used to define the quantum dot.

The quantum device illustrated in FIG. 3 includes an array of inducible quantum dots including a first quantum dot 301, a second quantum dot 302, a third quantum dot 303 and a fourth quantum dot 304. Each of the quantum dots 301-304 may be used as a qubit in the quantum device when occupied by a single electron. The occupation is controlled by controlling the voltage, V, supplied to the plunger gate of the quantum dot such that V₁ₑ≤V<V₂ₑ, wherein V₁ₑ is the minimum voltage required to occupy the quantum dot with one electron and V₂ₑ is the minimum voltage required to occupy the quantum dot with two electrons.

In this example the array is a one-dimensional array. However, in alternative examples the array is a two-dimensional array. Individual quantum dots can be addressed within the array using a crossbar array which includes bit lines and word lines. Optionally, two or more quantum dots can be grouped together such that a bit line and word line address more than one quantum dot simultaneously. This can help to reduce the circuitry required. FIG. 3 illustrates a bit line 305 and a word line 306. In this example, each of the first, second, third and fourth quantum dots 301-304 are connected to the same bit line 305 and word line 306. In an alternative example, each quantum dot may be connected to a separate bit line. The quantum dots may still be connected to the same word line.

The circuit shown in FIG. 3 includes a first, second, third and fourth integrated circuit elements 307, 308, 309, 310. In this example, each of the integrated circuit elements 307-310 comprises a floating gate metal-oxide-semiconductor field-effect transistor (FGMOS). Each integrated circuit element 307-310 includes a source, a drain, a control gate and a floating gate. In this example, the drain terminal of each integrated circuit element 307-310 is electrically connected to a respective quantum dot 301-304. Specifically, the drain terminal of each integrated circuit element 307-310 is electrically connected to a gate of a respective quantum dot 301-304. Each of the first to fourth integrated circuit elements 307-310 are electrically connected to the silicon layer (not shown) of the quantum device such that first, second, third and fourth output voltages V_{QD1}, V_{QD2}, V_{QD3}, V_{QD4} are applied to gates of the first, second, third and fourth induced quantum dots 301-304 respectively.

The source terminal of each integrated circuit element 307-310 is electrically connected to a voltage source. In this example, each of the integrated circuit elements 307-310 is connected to the same voltage source such that the input voltage of each of the integrated circuit elements 307-310 is the same, Vₛₑₜ. In an alternative example, there may be one or more additional voltage sources and the circuit may be configured such that each voltage source is electrically connected to a one or more integrated circuit elements. The resistance value of each integrated circuit element is tunable such that the voltage of the respective gate of the induced quantum dot can be controlled to effect a different output voltage for the same input voltage Vₛₑₜ. Modifying the threshold voltage of any of the first to fourth integrated circuit elements 307-310 can be used to tune the channel resistance R_{Fn} (n=1, 2, 3, 4) between the source and drain.

The output voltage V_{QDn} applied to each quantum dot 301-304 can be determined as follows, with n=1, 2, 3, 4:

$${V}_{QDn} = \frac{{R}_{n}}{{R}_{Fn} + {R}_{n}} {V}_{set}$$

For example, the input voltage Vₛₑₜ is divided according to the resistance R₁ of the first quantum dot 301 and the channel resistance R_{F1} of the first integrated circuit element 307 such that the output voltage V_{QD1} applied to the gate of the first quantum dot 301 is reduced according to the modifiable and non-volatile channel resistance R_{F1} of the first integrated circuit element 307. The channel resistance R_{F1} is also dependent on the tunable threshold voltage Vₜₕ.

In FIG. 3, the voltage source is configured to supply an input voltage Vₛₑₜ to the source terminals of each integrated circuit element 307-310. In this way, a single voltage source can be used to address all four quantum dots 301-304. This reduces the number of voltage sources and associated control circuitry required to address an array of qubits. Furthermore, the use of one voltage source to address multiple qubits reduces the number of operations required to perform a quantum computational process and can speed up the computation because the qubits can be manipulated globally and simultaneously across the quantum device. In further examples, there may be any number of quantum dots in the quantum device, typically arranged in a one-dimensional or two-dimensional array.

The circuit illustrated in FIG. 3 further comprises four field-effect transistors 311, 312, 313, 314. Each field-effect transistor 311-314 includes a source, a drain and a gate. The control gate of each integrated circuit element 307-310 is electrically connected to the drain terminal of a respective field-effect transistor 311-314. The source terminal of each field-effect transistor 311-314 is electrically connected to the word line 306. The gate terminal of each field-effect transistor 311-314 is electrically connected to the bit line 305. In this example, each field-effect transistor 311-314 is connected to the same word and bit lines 305, 306. In alternative examples, each field-effect transistor may be connected to different word and bit lines, or may be connected to the same word lines and different bit lines, or may be connected to different word lines and the same bit lines. The word and bit lines form a crossbar array across the array of qubits within the quantum device and can be used to selectively address particular qubits within the qubit array.

Each field-effect transistor 311-314 can be turned “on” by applying a suitable bias potential V_{FB} to the bit line 305. For a p-type field-effect transistor, if the gate voltage (i.e. the bias potential applied to the bit line 305) is lower than the threshold voltage (i.e. more negative), the field-effect transistor is “on” and the channel resistance is low. If the gate voltage is higher than the threshold voltage, the field-effect transistor is “off” and the channel resistance is high. When a bias potential is applied to the bit line 305 to turn the field-effect transistor “on”, current can flow from the source to the drain terminal of each field-effect transistor 311-314 due to the low channel resistance. The bias potential V_{FW} applied to the word line 306 can be adjusted to control the current flow. The current flow typically increases with increased bias potential applied to the word line 306 and the current may be proportional to the bias potential.

Accordingly, the field-effect transistors 311-314 can be used to tune the resistance value of each of the integrated circuit elements 307-310. When a field-effect transistor is enabled using an electrically connected bit line, the electrically isolated gate of an integrated circuit element which is electrically connected to that field-effect transistor can be charged or discharged. Charging and discharging of the electrically isolated gate can be controlled by modifying the bias potential applied to the word line which is electrically connected to the field-effect transistor. Individual integrated circuit elements 307-310, or groups of two or more integrated circuit elements 307-310, can be addressed using the crossbar array which includes the bit line 305 and the word line 306.

As described in relation to FIG. 2, the circuit provides a resistive division to reduce the input voltage Vₛₑₜ. For each quantum dot 301-304 the division is dependent on the channel resistance of the respective connected integrated circuit element 307-310 which is dependent on the tuned resistance value. The resistance value of each integrated circuit element 307-310 can be tuned using the respective connected field-effect transistor 311-314.

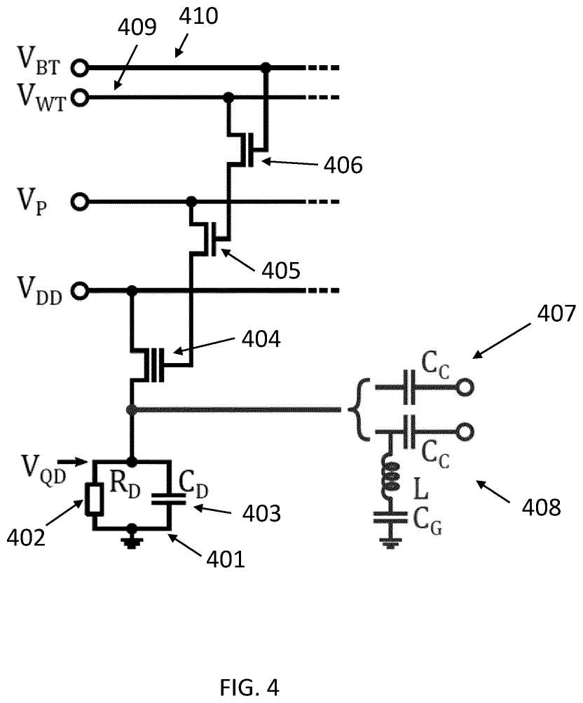

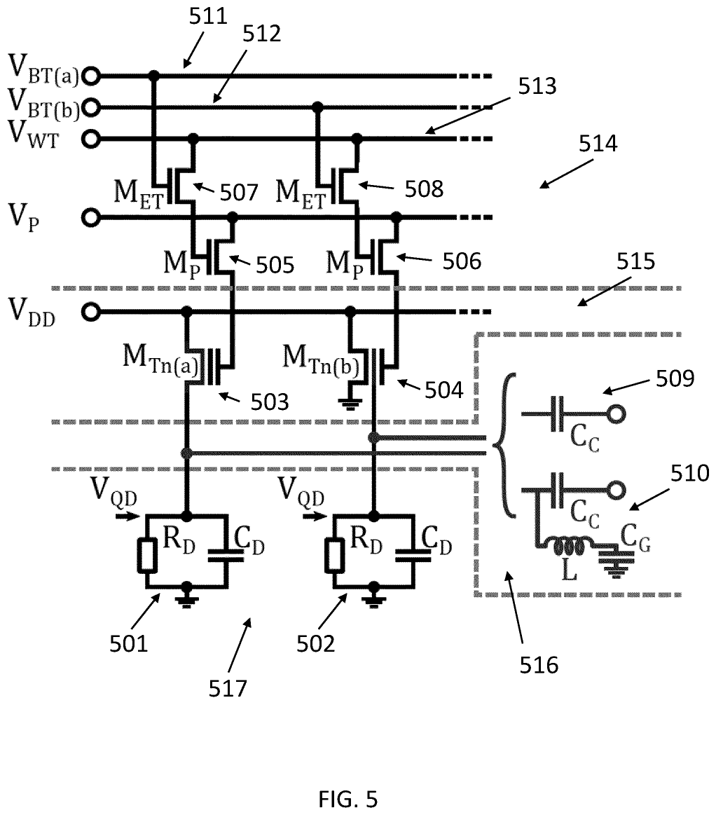

Each of the integrated circuit elements 307-310 provides an integrated addressable analogue memory in the quantum device and is capable of supplying a constant DC voltage offset to each the quantum dots 301-304 which is tailored to maintain the voltage within an acceptable range for qubit control. Specifically, for a plunger gate of an induced quantum dot, the acceptable range for qubit control is a voltage V which corresponds to the quantum dot containing a single electron, i.e. V₁ₑ≤V<V₂ₑ, wherein V₁ₑ is the minimum voltage required for a single electron to occupy the quantum dot and V₂ₑ is the minimum voltage required for two electrons to occupy the quantum dot. Each integrated circuit element 307-310 is used for controlling the voltage of respective plunger gates of the induced quantum dots 301-304. The supply of a tuned constant DC voltage offset to each of the quantum dots 301-304 can be combined with AC coupling of control signals as illustrated in FIGS. 4 and 5.

The input voltage Vₛₑₜ can be selected such that the output voltage V_{QDn} can be tuned to be within the acceptable range, i.e. V₁ₑ≤V_{QDn}<V2e. The exact values of V₁ₑ and V₂ₑ for each quantum dot will vary, but nominal values of these voltages can be used to determine a suitable input voltage Vₛₑₜ. Typically, V₁ₑ˜0.4V and V2e<2V₁ₑ. V_{QDn} does not need to exceed V₂ₑ. In order to occupy the quantum dot with a single quantum dot, the output voltage should be tuned such that V₁ₑ≤V_{QDn}<V₂ₑ. In order to empty the quantum dot, V_{QDn} should be tuned such that V<V₁ₑ.

In an example, Vₛₑₜ may be approximately equal to the nominal value of V₂ₑ. In this example, if the channel resistance R_{F1} of the first integrated circuit element 307 is much less than the resistance of the first quantum dot 301, i.e. R_{F1}<<R₁, the output voltage V_{QD1} applied to the first quantum dot 301 is approximately equal to V₂ₑ. If the channel resistance R_{F1} is similar to that of the first quantum dot 301, i.e. R_{F1}˜R₁, the output voltage V_{QD1} is approximately equal to half of the input voltage Vₛₑₜ, or V_{QD1}˜V₁ₑ. Accordingly, setting Vₛₑₜ to approximately V₂ₑ provides enough range in output voltage V_{QDn} to cover the necessary operating regime for each of the quantum dots.

The input voltage Vₛₑₜ can be further reduced to result in smaller output voltages V_{QDn} by increasing the channel resistance R_{Fn}. However, because the resistance Rₙ of the quantum dots is typically very large, particularly at cryogenic temperatures, it is difficult to achieve a very high channel resistance R_{Fn} such that R_{Fn}>>Rₙ.

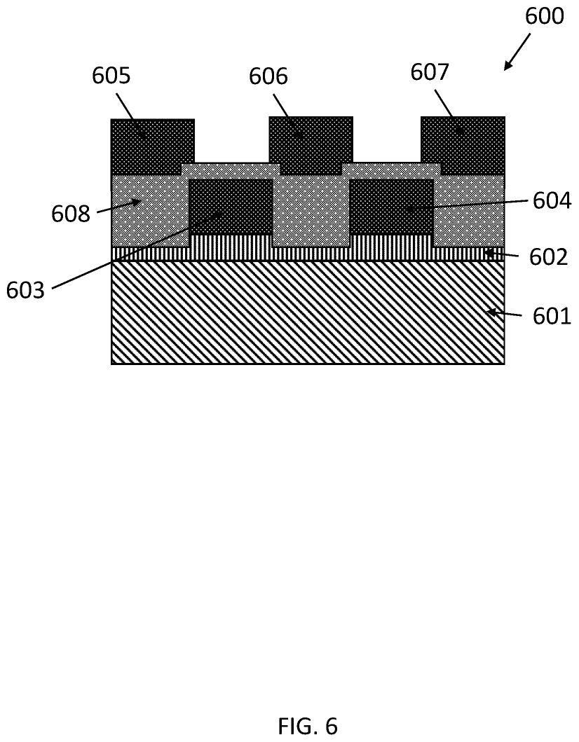

FIG. 4 is a circuit diagram illustrating a portion of a quantum device in accordance with an embodiment of the invention. The quantum device includes a qubit layer having a quantum dot 401 which can be used as a qubit. The circuit also includes a trimming layer having an integrated circuit element 404 used for voltage trimming as described herein. The circuit also includes a tuning layer for tuning the signal input comprising a first field-effect transistor 405. The circuit further includes a tuning selection layer comprising a second field-effect transistor 406 which is electrically connected to word and bit lines 409, 410 in a crossbar configuration. In this example, the integrated circuit element 404 comprises a silicon nanowire multiple quantum dot device similar to that illustrated in FIG. 6. In an alternative example, the integrated circuit element may comprise any gate-defined multiple quantum dot device.

Each of the integrated circuit element 404 and first and second field-effect transistors (FETs) 405, 406 include respective source, drain and gate terminals. The integrated circuit element 404 further comprises an electrically isolated element which is capacitively coupled to the gate terminal and capacitively coupled to the source-drain channel. The quantum device includes additional quantum dots which are not shown in this portion for simplicity.

In this example, for each gate of each quantum dot, the device includes an integrated circuit element and two FETs which are electrically connected as illustrated for the quantum dot 401 in FIG. 4. This configuration provides control for each individual gate of each individual quantum dot to account for variation in the properties of the quantum dot. The non-volatile resistance value of each integrated circuit element connected to a gate of a quantum dot can be tuned to control the output voltage applied to the gate of the induced quantum dot. In the example described below, the gate is a plunger gate. In alternative examples, the gate is a barrier gate and the output voltage applied by the integrated circuit element 404 can be used to adjust the height of the electrostatic barrier which defines an edge of an inducible quantum dot.

The quantum dot 401 is electrically connected to ground and is schematically illustrated as a resistor 402 having a resistance R_{D} and a capacitor 403 having a capacitance C_{D}. The quantum dot 401 is an electron spin quantum dot formed in a silicon layer of the quantum device. The quantum dot 401 can be induced by applying a voltage to a gate of the quantum dot 401; the number of electrons in the quantum dot 401 can be controlled by modifying the voltage applied to the quantum dot plunger gate.

The integrated circuit element 404 is electrically connected to the silicon layer in which the quantum dot 401 can be induced. In this example, the drain terminal of the integrated circuit element 404 is electrically connected to the quantum dot 401; the source terminal of the integrated circuit element 404 is electrically connected to a voltage source configured to supply an input voltage V_{DD}; and the gate terminal of the integrated circuit element 404 is electrically connected to the drain terminal of the first FET 405.

The configuration is such that the output voltage of the integrated circuit element 404 is applied to the gate of the induced quantum dot 401. The output voltage is dependent on the input voltage applied to the source terminal of the integrated circuit element 404 and the non-volatile resistance value of the integrated circuit element 404. The input voltage, applied using a voltage source, is typically applied to more than one quantum dot (not shown). This reduces the number of voltage sources required. The resistance value of each integrated circuit element connected to a gate of a respective quantum dot can be tuned such that the same input voltage can provide different output voltages to gates of different quantum dots as required according to the properties of each quantum dot.

In this example the non-volatile resistance value is tuned using the first FET 405 which may be referred to as a tuning FET 405. The drain terminal of the first FET 405 is electrically connected to the gate terminal of the integrated circuit element 404; the source terminal of the first FET 405 is electrically connected to a voltage source configured to supply a tuning signal V_{P}; and the gate terminal of the first FET 405 is electrically connected to the drain terminal of the second FET 406. The first FET 405 can be turned on and off by applying a large enough bias potential to the gate terminal using the second FET 406. When the first FET 405 is “on”, the first FET 405 is enabled and current can flow between the source and drain terminals of the first FET 405. When the first FET 405 is “off”, the first FET 405 is disabled and the source-drain current is negligible. Therefore when the first FET 405 is enabled, the tuning signal V_{P} is passed to the integrated circuit element 404, and when the first FET 405 is disabled, the tuning signal V_{P} is not passed to the integrated circuit element 404.

The current through the first FET 405 can be controlled by modifying the bias potential applied to the source terminal using the connected voltage source. The non-volatile resistance value of the integrated circuit element 404 can be tuned by altering the charge level of its electrically isolated element. The electrically isolated element can be charged and discharged by controlling the current flow through the first FET 405. For example, if the enabled first FET 405 is set up with a positive source-drain bias potential, i.e. if the tuning signal V_{P} is positive, the charge on the electrically isolated element will increase. Conversely, if the enabled first FET 405 is set up with a negative source-drain bias potential, i.e. if the tuning signal V_{P} is negative, the charge on the electrically isolated element will decrease (i.e. the electrically isolated element will discharge). Accordingly, the tuning FET 405 acts as a switch and is configured to tune the non-volatile resistance value of the integrated circuit element 404 only when the tuning FET 405 is enabled.

In this example, the first FET 405 is selected using the second FET 406. The second FET 406 may be referred to as a selector FET 406. The drain terminal of the second FET 406 is electrically connected to the gate terminal of the first FET 405; the source terminal of the second FET 406 is electrically connected to a word line 409; the gate terminal of the second FET 406 is electrically connected to a bit line 410. The bit and word lines 409, 410 form part of a crossbar array. The second FET can be turned on and off by applying a suitable bias potential to the bit line 410. The current through the second FET 406 can be modified by adjusting the bias potential applied to the source terminal of the second FET 406.

The second FET 406 can be enabled by applying a bias potential to the electrically connected bit and word lines 409, 410. The crossbar array comprises a plurality of bit lines and word lines (not shown) and is configured such that each second FET corresponding to a quantum dot can be selected. When the first and second FETs 405, 406 are enabled, an electrical connection is provided between the crossbar array and the integrated circuit element 404. For a quantum device with a plurality of quantum dots and thus a plurality of integrated circuit elements, the crossbar array is configured to be selectively electrically connected to any of the integrated circuit elements. In this way, the non-volatile resistance value for each integrated circuit element can be tuned individually.

The first and second FETs 405, 406 form tuning control circuitry and are used to set up the quantum device during a set-up stage. The integrated circuit element 404 forms a trimming layer and is used to trim the input voltage, i.e. to reduce the input voltage. The integrated circuit element 404 is enabled and tunable during the set-up stage. Subsequently, during normal operation, the integrated circuit element 404 is operated in the sub-threshold regime. Quantum operations can be performed during normal operation and the quantum device further includes a pulsing and readout layer comprising qubit pulsing control circuitry 407 and qubit readout control circuitry 408 to control the qubits during device operation.

The qubit pulsing control circuitry 407 and qubit readout control circuitry 408 are electrically connected between the integrated circuit element and the induced quantum dot. In this example the qubit pulsing control circuitry 407 comprises a capacitor having a capacitance Cc and a voltage source. The qubit pulsing control circuitry 407 is configured to modify the state of the qubit by applying a bias potential using the voltage source. The output voltage V_{QD} of the integrated circuit element 404 is configured to supply a constant DC offset voltage to induce the quantum dot and the qubit pulsing control circuitry 407 is configured to supply an AC control signal to the electron in the induced quantum dot and thus to modify the state of the electron spin qubit.

In this example the qubit readout control circuitry 408 comprises: a first capacitor having a capacitance C_{C}; a second capacitor having a capacitance to ground C_{G}; and an inductor having an inductance L. The qubit readout control circuitry 408 is configured to readout or infer the state of the qubit. Any suitable qubit readout control circuitry may be used and may be referred to as a tank circuit, an LC resonator, an LC tank circuit, a resonant circuit or a tuned circuit for example.

The qubit pulsing control circuitry and qubit readout control circuitry are electrically connected to a plurality of quantum dots within the array such that qubit states can be manipulated and read out for the plurality of quantum dots. Optionally, the qubit pulsing control circuitry and qubit readout control circuitry can be electrically connected to all of the quantum dots to control each of the quantum dots in the same manner simultaneously across the quantum device. Alternatively, the quantum dots within the device may be divided into two or more sub-groups of quantum dots and each sub-group may be electrically connected to qubit pulsing and qubit readout control circuitry. Global control of quantum dots in this manner reduces the control circuitry required to perform quantum operations.

In FIG. 4, the integrated circuit element 404 provides an addressable analogue memory, tunable using the first FET 405, which can supply a constant DC voltage offset V_{QD} to the quantum dot 401. The qubit pulsing control circuitry 407 and qubit readout control circuitry 408 are electrically connected between the integrated circuit element 404 and the quantum dot 401 and provide AC coupled control signals to tune and control the induced quantum dot 401. The quantum device typically comprises a plurality of quantum dots. The addressable analogue memory in the form of an integrated circuit element for each quantum dot can be used to individually tune the DC voltage offset for each quantum dot. The AC coupled control signals are applied to a plurality of quantum dots with different DC voltage offsets to achieve global control of a scaled qubit array.

In order to perform quantum operations using the quantum device, the quantum device is first set up during a set-up stage. During the set-up stage, a memory state is written by modifying the charge on the floating element of the integrated circuit element 404. The memory state is held stably over the duration of device operation; the memory is non-volatile with respect to the operating conditions of the integrated circuit element 404.

During the set-up stage, the non-volatile resistance value, R_{F}, of the integrated circuit element 404 is tuned to a set non-volatile resistance value, R_{F,set}. In this example, the integrated circuit element 404 is for controlling the voltage of the plunger gate of an inducible quantum dot 401. The set non-volatile resistance value, R_{F,set} is set such that the induced quantum dot 401 will be occupied by one electron when the input voltage V_{DD} is applied to the integrated circuit element 404, i.e. V₁ₑ<V_{QD}<V₂ₑ. The voltages V₁ₑ and V₂ₑ depend on the properties of the quantum dot 401 and thus the set non-volatile resistance value, R_{F,set} required for the plunger gate of each quantum dot in the array will vary accordingly.

The resistance value may be set using the tuning FET 405. The resistance value can be set and maintained at a fixed value without power input because the resistance value is non-volatile. This removes the need for refreshing the set-point during operation of the quantum device. In order to set the resistance value using the tuning FET 405, the tuning FET 405 is first enabled by applying bias potentials V_{BT}, V_{WT} to the word and bit lines 409, 410 which are electrically connected to the second FET 406 such that the tuning FET 405 is selected and turned “on”. When the tuning FET 405 is enabled, the resistance value of the integrated circuit element 404 can be tuned by applying a tuning voltage V_{P} to the source terminal of the tuning FET 405. The tuning FET 405 is electrically connected to the integrated circuit element 404 such that applying the tuning voltage V_{P} to the enabled tuning FET 405 can modify the resistance value R_{F} of the integrated circuit element 404. The set non-volatile resistance value R_{F,set} is dependent on the tuning voltage V_{P}.

Once the resistance value of the integrated circuit element 404 is tuned to the set resistance value, R_{F,set}, the control circuitry used in the set-up stage, i.e. the first and second FETs 405, 406, can be disabled and disconnected. This reduces the power consumption. The static charge stored by the electrically isolated, or floating, element of the integrated circuit element 404 is non-volatile and the set resistance value can therefore be maintained over the long term without needing to be refreshed. The integrated circuit element 404 is operated in the deep sub-threshold regime and does not require a power input.

During operation, an input voltage V_{DD} can be applied to the integrated circuit element 404. The output voltage V_{QD} of the integrated circuit element 404 is dependent on the input voltage V_{DD} and the set resistance value, R_{F,set}. The output voltage V_{QD} of the integrated circuit element 404 is applied to a gate of the induced quantum dot 401. In this example, the output voltage V_{QD} of the integrated circuit element 404 is applied to the plunger gate of the induced quantum dot 401 to control the electron occupancy of the quantum dot 401. In another example, the output voltage of the integrated circuit element is applied to a barrier gate of the induced quantum dot to control the height of the tunnel barrier and/or to control the tunnel coupling strength between the induced quantum dot and a neighbouring confinement region.

For a quantum device comprising a plurality of quantum dots, a gate of each quantum dot is electrically connected to a respective integrated circuit element which can be tuned according to the properties of that quantum dot. For example, the device may include first and second gates of first and second inducible quantum dots connected to first and second integrated circuit elements respectively which have first and second resistance values R_{F1}, R_{F2} and first and second threshold voltages Vₜₕ₁, Vₜₕ₂. During the set-up stage, a crossbar array for selecting one or more integrated circuit elements is used to select the first integrated circuit element by applying a suitable bias potential to the word and bit lines connected to the FET which is electrically connected to the first integrated circuit element. Following the selection of the first integrated circuit element, the first non-volatile resistance value R_{F1} is tuned to a first set non-volatile resistance value R_{F1,set} as described above.

Subsequently, the second integrated circuit element is selected by applying a suitable bias potential to the word and bit lines connected to the FET which is electrically connected to the first integrated circuit element. One of the word or bit lines may be common to both of the FETs connected to each of the first and second integrated circuit elements. If both the word and bit lines are in common, the tuning of the first and second resistance values R_{F1}, R_{F2}, would be performed simultaneously. However, typically individual control is desired due to the nature of the variation in properties between quantum dots. Following the selection of the second integrated circuit element, the second non-volatile resistance value R_{F2} is tuned to a second set non-volatile resistance value R_{F2,set} as described above.

Each n-th integrated circuit element in the quantum device can be selected and tuned in the set-up stage. An arbitrary channel resistance can be set for each integrated circuit element to form an analogue memory. The resistance value, and accordingly the threshold voltage and output voltage of the integrated circuit element applied to a gate of a related quantum dot, remains constant during the lifetime of the device and does not need to be refreshed.

The resistance value set-point for each quantum dot is typically selected such that a qubit resonance line is targeted. It is desirable to globally apply a driving frequency to the qubits, but the qubit resonance varies according to the electron g-factor which varies greatly across the device. The electron g-factor, gₑ, is nominally equal to 2, but the variation in gₑ−2 is approximately 10⁻². The electron g-factor can be modified using an applied electric field to induce a Stark shift, but this is not enough to overcome the g-factor variation as the Stark shift range, δgₑ=10⁻⁴−10⁻³. Cavity amplitude modulation can be used to overcome this: a single driving frequency can be split into 2N+1 frequency bands such that most or even all of the qubits can be addressed using a single driving frequency despite their differing g-factors. However, this requires tailored voltages for each quantum dot in the device such that each quantum dot is occupied by one and only one electron. The resistance value set-point for each quantum dot can be selected to meet this requirement.

Once the resistance values of each of the plurality of integrated circuit elements are tuned to the set resistance values, the control circuitry used in the set-up stage can be disabled and left idle. For non-volatile integrated circuit elements, the idle tuning control circuitry can be disconnected to reduce any latent power consumption or heat load. During operation, the same input voltage V_{DD} can be applied to the first and second integrated circuit elements (and any further integrated circuit elements within the quantum device). The first and second output voltages of the integrated circuit elements depend on the input voltage V_{DD} and the first and second set resistance values, R_{F1,set}, R_{F2,set}. The first output voltage of the first integrated circuit element is applied to the plunger gate of the first induced quantum dot to control its voltage for single electron occupancy. The second output voltage of the second integrated circuit element is applied to the plunger gate of the second induced quantum dot to control its voltage for single electron occupancy. Similarly, the n-th output voltage of the n-th integrated circuit element is applied to the plunger gate of the n-th induced quantum dot to control its voltage for single electron occupancy.

Typically, the quantum device may be operated at cryogenic temperatures. The properties of the quantum device such as the threshold voltage and channel resistance typically vary with temperature. Accordingly, the set-up stage is typically performed at the desired operation temperature prior to device operation. The device can be re-set by following the set-up stage procedure as described above. The device may be re-set when a re-tuning or re-configuration of the device is desired.

FIG. 5 is a circuit diagram illustrating a portion of a quantum device in accordance with an embodiment of the invention. The circuit includes: a tuning layer 514 comprising tuning elements and a crossbar array for enabling the selection of the tuning elements; a trimming layer 515 comprising integrated circuit elements configured to output a constant DC offset voltage; a pulsing and readout layer 516 comprising AC coupled inputs configured to modify the DC offset voltage to control qubits; and a qubit layer 517 comprising electron spin qubits formed from single quantum dots induced by applying voltages to gates of the inducible quantum dots.

The circuit includes: first and second quantum dots 501, 502 in the qubit layer 517; first and second integrated circuit elements 503, 504 in the trimming layer 515; first and third field-effect transistors (FETs) 505, 506 in the tuning layer 514; and second and fourth FETs 507, 508 in the tuning layer 514. The first and second quantum dots 501, 502 are electrically connected to a ground potential. The circuit also includes a qubit pulsing input 509 forming qubit pulsing control circuity and a tank circuit input 510 forming qubit readout control circuitry. The qubit pulsing and readout control circuitry 509, 510 is arranged within the pulsing and readout layer 516.

In FIG. 5, the circuit elements relating to the first quantum dot 501 are electrically connected according to a first configuration and the circuit elements relating to the second quantum dot 502 are electrically connected according to a second configuration. Typically, the quantum dots in a quantum device would be each be connected to the related circuit elements according to either the first configuration or the second configuration. Optionally, some quantum dots in the device are connected according to the first configuration and other quantum dots in the device are connected according to the second configuration.

In the first configuration, the first quantum dot 501, first integrated circuit element 503, first FET 505 and second FET 507 are electrically connected as described in relation to FIG. 4. The resistance value of the first integrated circuit element 503 can be tuned with respect to the input voltage V_{DD} connected to the drain terminal of the first integrated circuit element 503. The input voltage V_{DD} is a global voltage reference. The non-volatile resistance value of the first integrated circuit element 503 is the channel resistance of the first integrated circuit element 503. This channel resistance, when placed in series with a load resistance such as the resistance R_{D} of the first quantum dot 501, forms a common voltage divider configuration. Accordingly, the voltage seen at the load (i.e. the first quantum dot 501) is reduced with respect to the supply (i.e. the input voltage V_{DD}).

In the second configuration, the second quantum dot 502 is electrically connected to the electrically isolated element of the second integrated circuit element 504. The drain of the second integrated circuit element 504 is connected to ground. The electrical connections between the second integrated circuit element 504, third FET 506 and fourth FET 508 are configured to be the same as the electrical connections between first integrated circuit element 503, first FET 505 and second FET 507. The electrically isolated element is capacitively coupled to the source-drain channel and to the gate terminal of the second integrated circuit element 504 and thus there is a DC voltage offset which can be applied to a gate of the second quantum dot 502. The electrically isolated element of the second integrated circuit element is directly connected to the gate of the second quantum dot 502.

The circuit illustrated in FIG. 5 includes a crossbar array having a first bit line 511, a second bit line 512 and a word line 513. In this example, the source terminals of both the second FET 506 and the fourth FET 508 are electrically connected to the word line 513. The gate terminals of the second and fourth FETs 506, 508 are electrically connected to separate bit lines: the first bit line 511 is electrically connected to the second FET 506 and the second bit line 512 is electrically connected to the fourth FET 508. In an alternative example in which the first and second quantum dots are both connected according to the same configuration, the arrangement of the second and fourth FETs 506, 508 with respect to the word and bit lines 511-513 can also be as illustrated in FIG. 5.

The crossbar array is configured to be selectively electrically connected to the first and/or second integrated circuit elements 503, 504. Selective electrical connection is achieved by modifying the bias potential applied to each of the first and second bit lines 511, 512 and the word line 513. Each of the first and second bit lines 511, 512 and the word line 513 are electrically connected to a voltage source which is configured to supply a controllable bias potential. When a bias potential V_{BT(a)} greater than the threshold voltage of the second FET 506 is applied to the first bit line 511, the second FET 506 is enabled, i.e. the source-drain channel resistance is low and the second FET 506 is in the “on” state. When a bias potential V_{BT(b)} greater than the threshold voltage of the fourth FET 508 is applied to the second bit line 512, the fourth FET 508 is enabled. If the bias potential V_{BT(a)}, V_{BT(b)} applied to the first or second bit lines 511, 512 is lower than the threshold voltage of the second or fourth FETs 506, 508 respectively, that FET is disabled, i.e. the source-drain channel resistance is high and the second or fourth FET 506, 508 is in the “off” state.

When the second and/or fourth FETs 506, 508 are enabled, the bias potential V_{WT} applied to the word line 513 can be adjusted to control the source-drain current through the second and/or fourth FETs 506, 508. In an example, the bias potential V_{BT (a)} applied to the first bit line 511 is greater than the threshold voltage of the second FET 506 and the bias potential V_{BT (b)} applied to the second bit line 512 is lower than the threshold voltage of the fourth FET 508. In this example, when a bias potential V_{WT} is applied to the word line 513, the signal is passed through the second FET 506 to enable the first FET 505 but is not passed through the fourth FET 508 to the third FET 507. Accordingly, a bias potential V_{P} applied to the source terminal of the first and third FETs 505, 507 can be used to modify the resistance value of the first integrated circuit element 503, but the signal is not passed through to the second integrated circuit element 504.

FIG. 6 schematically illustrates a cross-sectional side view of an integrated circuit element 600. The integrated circuit element 600 illustrated in FIG. 6 is a silicon nanowire multiple quantum dot device fabricated by patterning silicon nanowires onto a thinned silicon-on-insulator substrate. The integrated circuit element 600 has been found to exhibit hysteretic behaviour in the threshold voltage and the corresponding channel resistance.

The integrated circuit element 600 comprises a silicon layer 601. A first dielectric layer 602 is disposed on the silicon layer 601. In this example the first dielectric layer 602 comprises thermally grown silicon dioxide, SiO₂. The integrated circuit element 600 comprises five polycrystalline silicon (polysilicon) gates 603-607 deposited in two stages. In a first stage, a first polysilicon gate 603 and a second polysilicon gate 604 are deposited. In this example, the first and second polysilicon gates 603, 604 are approximately 50 nanometres thick and are deposited simultaneously.

Following the deposition of the first and second polysilicon gates 603, 604, a second dielectric layer 608 is deposited. In this example, the second dielectric layer 608 is approximately 35 nanometres thick SiO₂ and is grown using low-pressure chemical vapour deposition (LPCVD). Third, fourth and fifth polysilicon gates 605, 606, 607 are deposited on top of the second dielectric layer 608. In this example, the third, fourth and fifth polysilicon gates 605, 606, 607 are approximately 80 nanometres thick and are deposited simultaneously.

Each of the first, second and fourth polysilicon gates 603, 604, 606 are approximately 100 nanometres wide. The fourth polysilicon gate 606 is positioned in between the first and second polysilicon gates 603, 604 and may overlap each of these by approximately 10 nanometres. The third polysilicon gate 605 may overlap the first polysilicon gate 603 by approximately 10 nanometres. The fifth polysilicon gate 607 may overlap the second polysilicon gate by approximately 10 nanometres. The second dielectric layer 608 acts as an electrically insulating barrier between the first and second polysilicon gates 603, 604 and the third, fourth and fifth polysilicon gates 605, 606, 607.

The third and fifth polysilicon gates 605, 607 provide source and drain terminals and extend to charge reservoirs. The first, second and fourth polysilicon gates 603, 604, 606 define quantum dots at the interface between the silicon layer 601 and the first dielectric layer 602.

In alternative examples, the integrated circuit element may comprise a different number of polysilicon gates: for example seven, or three. Typically the polysilicon gates are deposited in two layers separated by an electrically insulating layer. Further examples of devices which may be suitable for use as an integrated circuit element are disclosed in Duan et al, “Dispersive readout of reconfigurable ambipolar quantum dots in a silicon-on-insulator nanowire”, arXiv: 2009.13944v1 [cond-mat.mes-hall] (2020).

In further alternative examples, the integrated circuit element is a conventional floating gate metal-oxide-semiconductor field-effect-transistor.

As will be appreciated, a quantum device including an integrated circuit element for controlling the voltage applied to a gate of an inducible quantum dot is disclosed along with a method for using the device. The integrated circuit element provides an addressable analogue memory: the resistance value of the integrated circuit element can be tuned to provide a controllable voltage to the gate of the quantum dot which can maintained during the course of the device operation at cryogenic temperatures and does not need to be refreshed. During device operation, AC coupled control signals are used to modify and read out the state of qubits in the device.

1. A quantum device, comprising:
a silicon layer in which a plurality of quantum dots can be induced;
a first set of gates of a first inducible quantum dot for controlling an electrical potential that defines a first induced quantum dot, wherein the first set of gates comprises two first barrier gates and a first plunger gate, wherein a first gate of the first set of gates is the first plunger gate or one of the first barrier gates;
a second set of gates of a second inducible quantum dot for controlling an electrical potential that defines a second induced quantum dot, wherein the second set of gates comprises two second barrier gates and a second plunger gate, wherein a second gate of the second set of gates is the second plunger gate or one of the second barrier gates;
a first integrated circuit element for controlling the voltage of the first gate, the first integrated circuit element having a first non-volatile resistance value, R_{F}, which is tunable; and
a second integrated circuit element for controlling the voltage of the second gate, the second integrated circuit element having a second non-volatile resistance value which is tunable;
wherein the first integrated circuit element has an input voltage and a first output voltage, wherein the first output voltage is dependent on the input voltage and the first non-volatile resistance value;
wherein the second integrated circuit element has the input voltage and a second output voltage, wherein the second output voltage is dependent on the input voltage and the second non-volatile resistance value; and
wherein the first and second integrated circuit elements are electrically connected to the first and second gates, respectively, such that the first and second output voltages are applied to the first gate of the first inducible quantum dot and the second gate of the second inducible quantum dot, respectively.

2. A quantum device according to claim 1, wherein the first and/or second integrated circuit element comprises a floating gate metal-oxide-semiconductor field-effect transistor.

3. A quantum device according to claim 1, wherein the first and/or second integrated circuit element comprises a gate-defined multiple quantum dot device.

4. A quantum device according to claim 1, wherein:
the first inducible quantum dot, when induced, has a first resistance value, R_{D}; and
the first output voltage, Vₒᵤₜ, is proportional to the input voltage, Vᵢₙ, with a constant of proportionality equal to R_{D}/(R_{F}+R_{D}).

5. A quantum device according claim 1, further comprising a tuning field effect transistor, FET, wherein the tuning FET is electrically connected to the first or second integrated circuit element and the tuning FET is configured to enable or disable a tuning voltage for the first or second integrated circuit element, respectively.

6. A quantum device according to claim 1, wherein the first and/or second induced quantum dots are for use as qubits.

7. A quantum device according to claim 6, further comprising qubit pulsing control circuitry configured to modify the state of the first and/or second qubit, wherein the qubit pulsing control circuitry is electrically connected between the first and/or second integrated circuit element and the first and/or second induced quantum dot, respectively.

8. A quantum device according to claim 6, further comprising qubit readout control circuitry configured to readout the state of the first and/or second qubit, wherein the qubit readout control circuitry is electrically connected between the first and/or second integrated circuit element and the first and/or second induced quantum dot, respectively.

9. A quantum device according to claim 1, further comprising a crossbar array configured to be selectively electrically connected to the first and/or second integrated circuit elements.

10. A method for using a quantum device comprising: a silicon layer in which a plurality of quantum dots can be induced; a first set of gates of a first inducible quantum dot for controlling an electrical potential that defines a first induced quantum dot, wherein the first set of gates comprises two first barrier gates and a first plunger gate, wherein a first gate of the first set of gates is the first plunger gate or one of the first barrier gates; a second set of gates of a second inducible quantum dot for controlling an electrical potential that defines a second induced quantum dot, wherein the second set of gates comprises two second barrier gates and a second plunger gate, wherein a second gate of the second set of gates is the second plunger gate or one of the second barrier gates; a first integrated circuit element for controlling the voltage of the first gate, the first integrated circuit element having a first non-volatile resistance value, R_{F}, which is tunable; a second integrated circuit element for controlling the voltage of the second gate, the second integrated circuit element having a second non-volatile resistance value which is tunable; and a crossbar array for selecting one or more integrated circuit elements, wherein the method comprises:
inducing the first and second quantum dots;
selecting the first integrated circuit element;
tuning the first non-volatile resistance value of the first integrated circuit element to a first set non-volatile resistance value;
selecting the second integrated circuit element;
tuning the second non-volatile resistance value of the second integrated circuit element to a second set non-volatile resistance value;
applying an input voltage to the first and second integrated circuit elements, wherein a first output voltage of the first integrated circuit element and a second output voltage of the second integrated circuit element are dependent on the input voltage and the first and second set non-volatile resistance values, respectively;
applying the first output voltage of the first integrated circuit element to the first gate of the first induced quantum dot; and
applying the second output voltage of the second integrated circuit element to the second gate of the second induced quantum dot.

11. A method according to claim 10, wherein the quantum device further comprises a tuning field effect transistor, FET, comprising source, drain and gate terminals, and wherein tuning the first or second non-volatile resistance value of the first or second integrated circuit element to the first or second set non-volatile resistance value respectively comprises:
enabling the tuning FET by applying a voltage to the gate terminal of the tuning FET to allow current to pass between the source and drain terminals of the tuning FET; and
applying a tuning voltage to the tuning FET;
wherein the tuning FET is electrically connected to the first or second integrated circuit element such that applying the tuning voltage to the enabled tuning FET modifies the non-volatile resistance value of the first or second integrated circuit element, respectively; and
wherein the first and second set non-volatile resistance values are dependent on the tuning voltage.
